(19) United States
(12) Patent Application Publication
(10) Pub. No.: US 2016/0134281 A1
(43) Pub. Date: May 12, 2016

(54) SWITCH ISOLATION NETWORK

(71) Applicant: SKYWORKS SOLUTIONS, INC., Woburn, MA (US)

(72) Inventors: Haki CEBI, Waltham, MA (US); Fikret ALTUNKILIC, North Andover, MA (US)

(21) Appl. No.: 14/802,826

(22) Filed: Jul. 17, 2015

Related U.S. Application Data
(60) Provisional application No. 62/000,234, filed on May 19, 2014.

(51) Int. Cl. H03K 17/687

(52) U.S. Cl. CPC H03K 17/687

(57) ABSTRACT

Radio-frequency (RF) switches and devices are disclosed providing improved switch isolation. Disclosed RF switches may include a pole node, a first throw arm connected between the pole node and a first throw node, and a second throw arm connected between the pole node and a second throw node, the second throw arm including first and second field-effect transistors (FETs). RF switches may further include a passive device connected on a first end to a source connector of the first FET and on a second end to a drain connector of the second FET.

### RELATED APPLICATION

This application claims priority to U.S. Provisional Application No. 62/000,234, filed on May 19, 2014, entitled SWITCH ISOLATION NETWORK, the disclosure of which is hereby incorporated by reference in its entirety.

### BACKGROUND

1. Field

The present disclosure generally relates to the field of electronics, and more particularly, to radio-frequency switches.

2. Description of Related Art

Radio-frequency (RF) switches, such as transistor switches, can be used to switch signals between one or more poles and one or more throws. RF signal isolation, or lack thereof, in connection with branches or components of RF switches can affect switching performance.

### SUMMARY

Relatively high isolation for switching devices and systems can be desirable. A trade-off may generally exist between isolation and insertion loss in certain systems/devices. Certain isolation techniques may not provide adequate isolation as frequency increases. Certain embodiments disclosed herein provide relatively high isolation at relatively high frequencies through the use of device parasitics and/or a relatively high value parallel resistor.

While certain isolation techniques may utilize many stages and shunt devices to provide switch isolation, such techniques may be insufficient as the device parasitics increase at higher frequencies. Certain embodiments disclosed herein utilize the device parasitics and/or resonant structure to provide improved isolation at frequencies of interest. Such technique(s) may be particularly useful for CMOS and/or Silicon-on-Insulator (SOI) switches, where significant parasitic capacitance may exist between drain and body, and between body and source terminals. This is different than drain to source parasitic capacitor as in the case of GaAs FETs.

Certain embodiments disclosed herein improve switch isolation through the use of one or more resistor networks or networks comprising other passive devices. Resistor values may be tuned for optimal isolation depending on the desired frequency of isolation. In certain embodiments, the resistive network, with the parasitc capacitance of the devices may provide a resonant structure to create a substantially-open circuit and isolate multiple RF ports.

In some implementations, the present disclosure relates to a radio-frequency (RF) switch including a pole node, a first throw arm connected between the pole node and a first throw node, a second throw arm connected between the pole node and a second throw node, the second throw arm including first and second field-effect transistors (FETs), and a passive device connected on a first end to a source connector of the first FET and on a second end to a drain connector of the second FET.

The passive device may be a resistor and/or an inductor. In certain embodiments, the pole node is connected to the first or second end of the passive device. The second throw node may be connected to the first or second end of the passive device. In certain embodiments, the RF switch further includes a first shunt arm connected to the first throw arm and a second shunt arm connected to the second throw arm. The second shunt arm may be connected to the second throw arm between the first FET and the second FET.

In certain embodiments, the first and second FETs are connected in series. When the second throw arm is in an OFF state, the passive device may be configured to resonate a parasitic capacitance of at least one of the first and second FETs to at least partially isolate the first arm from the second throw node.

Certain embodiments disclosed herein provide a process for operating a radio-frequency (RF) switch. The process may include transmitting an RF signal between a pole node and a first throw node, controlling first and second field-effect transistors (FETs) of a throw arm connected between the pole node and a second throw node so that at least one of the first and second FETs is in an OFF state, and resonating parasitic capacitance associated with one or more of the first and second FETs using a passive device connected on a first end to a source connector of the first FET and on a second end to a drain connector of the second FET. The passive device may be a resistor and/or an inductor. In certain embodiments, the process further includes isolating the first throw node from the second throw node at least in part by said resonating.

Certain embodiments disclosed herein provide a semiconductor die including a semiconductor substrate, a pole node, a first throw arm formed on the semiconductor substrate and connected between the pole node and a first throw node, a second throw arm formed on the semiconductor substrate and connected between the pole node and a second throw node, the second throw arm including first and second field-effect transistors (FETs), and a passive device connected on a first end to a source connector of the first FET and on a second end to a drain connector of the second FET. The passive device may be a resistor and/or an inductor.

The pole node may be connected to the first or second end of the passive device. In certain embodiments, the second throw node is connected to the first or second end of the passive device. The semiconductor die may further include a first shunt arm connected to the first throw arm and a second shunt arm connected to the second throw arm. The second shunt arm is connected to the second throw arm between the first FET and the second FET. The first and second FETs may be connected in series. In certain embodiments, when the second throw arm is in an OFF state, the passive device is configured to resonate a parasitic capacitance of at least one of the first and second FETs to at least partially isolate the first arm from the second throw node.

Certain embodiments provide a wireless device including a transceiver configured to process RF signals, an antenna in communication with the transceiver configured to facilitate transmission of an amplified RF signal, a power amplifier connected to the transceiver and configured to generate the amplified RF signal, and a switch connected to the antenna and the power amplifier and configured to selectively route the amplified RF signal to the antenna, the switch including a pole node, a first throw arm connected between the pole node and a first throw node, and a second throw arm formed on the semiconductor substrate and connected between the pole node and a second throw node, the second throw arm including first and second field-effect transistors (FETs), the switch further including a passive device connected on a first end to a source connector of the first FET and on a second end to a drain connector of the second FET.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 schematically shows a radio-frequency (RF) switch configured to switch one or more signals between one or more poles and one or more throws according to one or more embodiments.

FIG. 2 shows an RF switch including an RF core and an energy management (EM) core according to one or more embodiments.

FIG. 3 shows an example of the RF core implemented in a single-pole-double-throw (SPDT) configuration according to one or more embodiments.

FIG. 4 shows an example of an RF core implemented in an SPDT configuration where each switch arm includes a plurality of field-effect transistors (FETs) connected in series according to one or more embodiments.

FIG. 5 shows an example RF core according to one or more embodiments.

FIG. 6 shows an example RF core according to one or more embodiments.

FIG. 7 shows an example RF core according to one or more embodiments.

FIG. 8 shows an example RF core according to one or more embodiments.

FIGS. 9A and 9B are graphs showing potential gain for switching devices according to one or more embodiments.

FIGS. 10A and 10B are graphs showing potential gain for switching devices according to one or more embodiments.

FIG. 11 shows an example of how various components for switching, and/or switch isolation can be implemented according to one or more embodiments.

FIGS. 12 and 13 show an example of a packaged module that can include one or more features described herein.

FIG. 14 shows that in some embodiments, one or more features of the present disclosure can be implemented in a switch device such as a single-pole-multi-throw (SPMT) switch configured to facilitate multi-band multi-mode wireless operation.

FIG. 15 shows an example of a wireless device that can include one or more features described herein.

### DETAILED DESCRIPTION

The headings provided herein are for convenience only and do not necessarily affect the scope or meaning of the claimed invention. Disclosed herein are example configurations and embodiments relating to high-isolation radiofrequency (RF) switches.

### Example Components of a Switching Device:

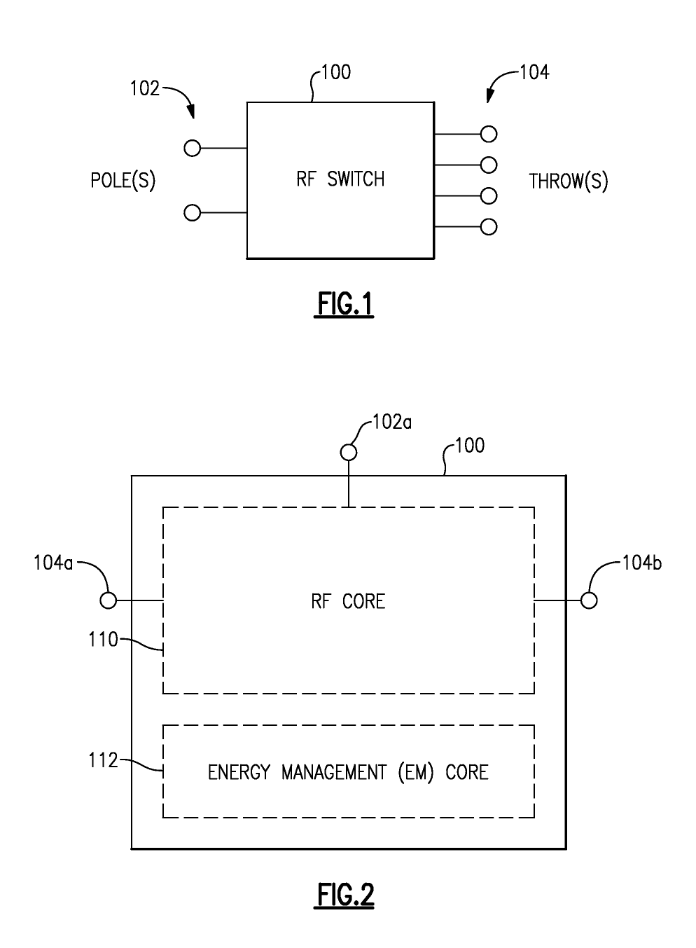

FIG. 1 schematically shows an RF switch 100 configured to switch one or more signals between one or more poles 102 and one or more throws 104. In some embodiments, such a switch can be based on one or more field-effect transistors (FETs) such as silicon-on-insulator (SOI) FETs. When a particular pole is connected to a particular throw, such a path is commonly referred to as being closed or in an ON state. When a given path between a pole and a throw is not connected, such a path is commonly referred to as being open or in an OFF state.

FIG. 2 shows that in some implementations, the RF switch 100 of FIG. 1 can include an RF core 110 and an energy management (EM) core 112. The RF core 110 can be configured to route RF signals between the first and second ports. In the example single-pole-double-throw (SPDT) configuration shown in FIG. 2, such first and second ports can include a pole 102a and a first throw 104a, or the pole 102a and a second throw 104b.

In some embodiments, the EM core 112 can be configured to supply, for example, voltage control signals to the RF core 110. The EM core 112 can be further configured to provide the RF switch 100 with logic decoding and/or power supply conditioning capabilities.

In some embodiments, the RF core 110 can include one or more poles and one or more throws to enable passage of RF signals between one or more inputs and one or more outputs of the switch 100. For example, the RF core 110 can include a single-pole double-throw (SPDT or SP2T) configuration as shown in FIG. 2.

In the example SPDT context, FIG. 3 shows a more detailed example configuration of an RF core 110. The RF core 110 is shown to include a single pole 102a coupled to first and second throw nodes 104a, 104b via first and second transistors (e.g., FETs) 120a, 120b. The first throw node 104a is shown to be coupled to an RF ground via a FET 122a to provide shunting capability for the node 104a. Similarly, the second throw node 104b is shown to be coupled to the RF ground via a FET 122b to provide shunting capability for the node 104b.

In an example operation, when the RF core 110 is in a state where an RF signal is being passed between the pole 102a and the first throw 104a, the FET 120a between the pole 102a and the first throw node 104a can be in an ON state, and the FET 120b between the pole 102a and the second throw node 104b can be in an OFF state. For the shunt FETs 122a, 122b, the shunt FET 122a can be in an OFF state so that the RF signal is not shunted to ground as it travels from the pole 102a to the first throw node 104a. The shunt FET 122b associated with the second throw node 104b can be in an ON state so that any RF signals or noise arriving at the RF core 110 through the second throw node 104b is shunted to the ground so as to reduce undesirable interference effects to the pole-to-first-throw operation.

Although the foregoing example is described in the context of a single-pole-double-throw configuration, it will be understood that the RF core can be configured with other numbers of poles and throws. For example, there may be more than one pole, and the number of throws can be less than or greater than the example number of two.

In the example of FIG. 3, the transistors between the pole 102a and the two throw nodes 104a, 104b are depicted as single transistors. In some implementations, such switching functionalities between the pole(s) and the throw(s) can be provided by switch arm segments, where each switch arm segment includes a plurality of transistors, such as FETs.

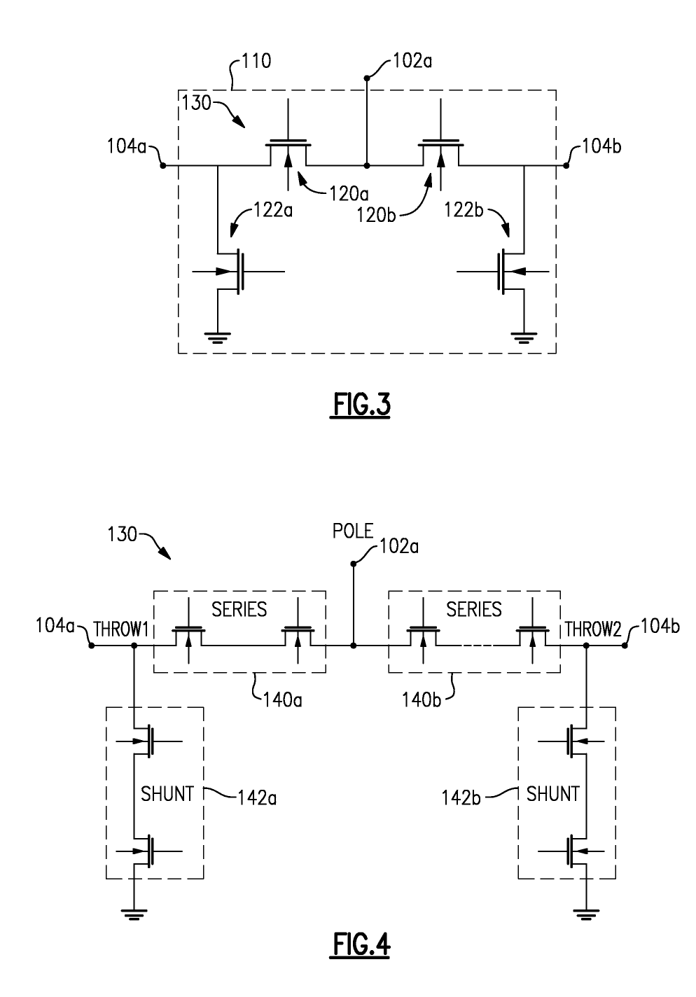

An example RF core configuration 130 of an RF core having such switch arm segments is shown in FIG. 4. In the example, the pole 102a and the first throw node 104a are shown to be coupled via a first switch arm segment 140a. Similarly, the pole 102a and the second throw node 104b are shown to be coupled via a second switch arm segment 140b. The first throw node 104a is shown to be capable of being shunted to an RF ground via a first shunt arm segment 142a. Similarly, the second throw node 104b is shown to be capable of being shunted to the RF ground via a second shunt arm segment 142b.

In an example operation, when the RF core 130 is in a state where an RF signal is being passed between the pole 102a and the first throw node 104a, all of the FETs in the first switch arm segment 140a can be in an ON state, and all of the FETs in the second switch arm segment 104b can be in an OFF state. The first shunt arm 142a for the first throw node 104a can have all of its FETs in an OFF state so that the RF signal is not shunted to ground as it travels from the pole 102a to the first throw node 104a. All of the FETs in the second shunt arm 142b associated with the second throw node 104b can be in an ON state so that any RF signals or noise arriving at the RF core 130 through the second throw node 104b is shunted to the ground so as to reduce undesirable interference effects to the pole-to-first-throw operation.

Again, although described in the context of an SP2T configuration, it will be understood that RF cores having other numbers of poles and/or throws can also be implemented in certain embodiments.

In some implementations, a switch arm segment (e.g., 140a, 140b, 142a, 142b) can include one or more semiconductor transistors such as FETs. In some embodiments, an FET may be capable of being in a first state or a second state and can include a gate, a drain, a source, and a body (sometimes also referred to as a substrate). In some embodiments, an FET can include a metal-oxide-semiconductor field effect transistor (MOSFET). In some embodiments, one or more FETs can be connected in series forming a first end and a second end such that an RF signal can be routed between the first end and the second end when the FETs are in a first state (e.g., ON state).

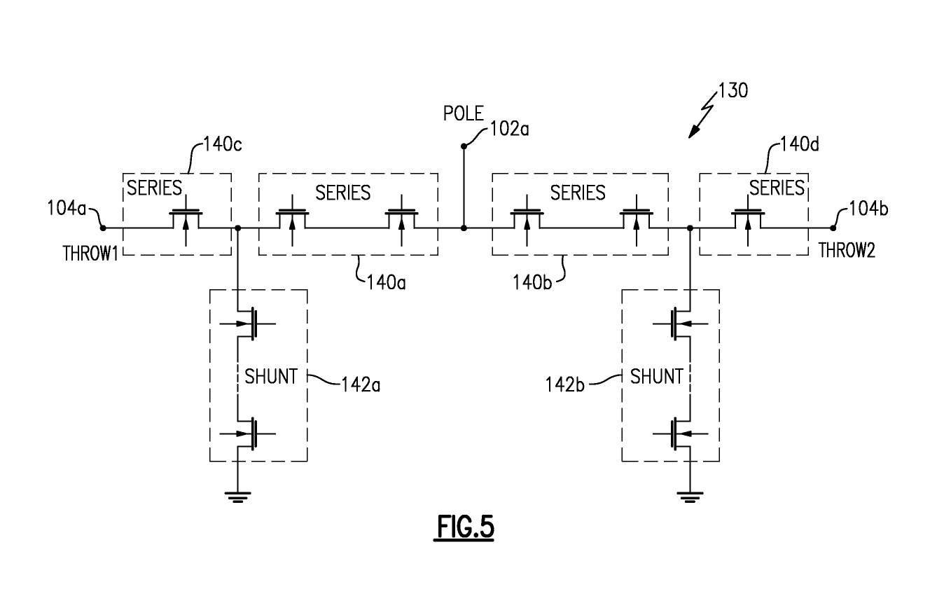

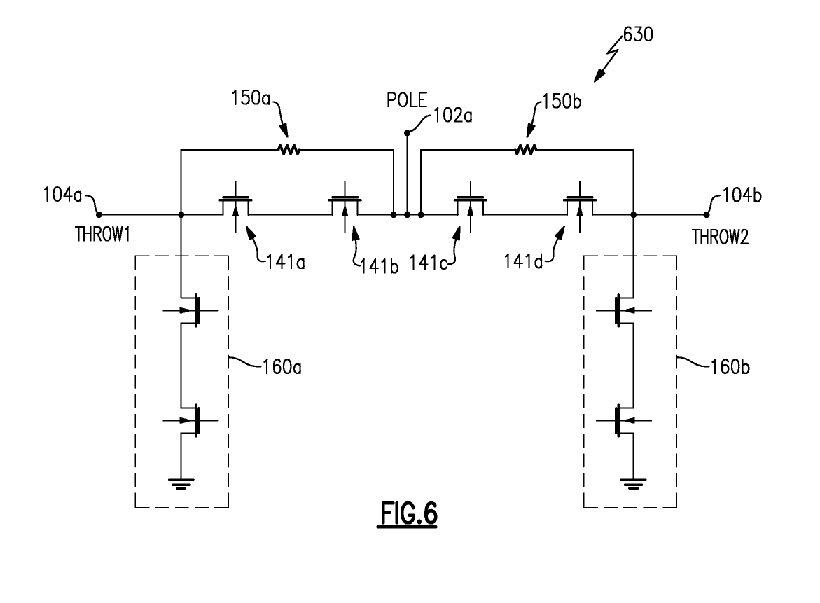

The circuit configuration shown in FIG. 4 may be considered a series-shunt configuration, wherein the series and shunt portions of the circuit 130 are identified in the diagram. In addition to series-shunt switches, other types of switches may be implemented within the scope of the present disclosure according to certain embodiments. FIG. 5 illustrates one possible example switch configuration, referred to herein as a series-shunt-series configuration. The RF core circuitry 130 of FIG. 5 includes a pole 102a and the first throw node 104a coupled via a first series switch arm segment 140a. Similarly, the pole 102a and the second throw node 104b are shown to be coupled via a second series switch arm segment 140b. Furthermore, the first throw node 104a is shown to be capable of being shunted to an RF ground via a first shunt arm segment 142a and the second throw node 104b is shown to be capable of being shunted to the RF ground via a second shunt arm segment 142b.

The circuit 130 of FIG. 5 further includes one or more additional series arm segments 140c, 140d. Although each of the series segments 140c, 140d is shown comprising a single transistor device, any desirable number of transistor devices (e.g. FETs) may be included in the series arm segments.

### Switch Isolation:

As described above, switch circuits having relatively high isolation characteristics may be desirable in certain applications. For example, with further reference to FIG. 5, when the switch circuit 110 transmits high power from port 102a to one of the throws, such as throw 1 (104a), the series arm of the non-transmitting section of the circuit 130 may generally be in an OFF state to provide high isolation to throw 1. However, device parasitics present on the OFF-state FETs of the OFF arm (e.g., drain-to-source parasitic capacitance) can have a detrimental effect on the isolation performance of the circuit 130 as a result of RF energy leakage from the port to the OFF throw, or vice versa. While an increase in the number of FETs of the switch circuit 130 can increase the power-handling capacity of the switch and potentially reduce signal distortion, additional series FETs can contribute to increased insertion loss.

Switch isolation may be achieved to some degree through the use of additional stages and/or shunt devices. However, such solutions may be inadequate at higher frequencies as the effect of device parasitics increases. Furthermore, the use of multiple stages can increase insertion loss. While certain switching solutions do not provide relatively high isolation at certain high frequencies, embodiments disclosed herein provide high isolation at high frequency though the use of device parasitics in combination with the insertion of one or more additional parallel devices, such as one or more high-value parallel resistors. For example, device parasitics may be combined with a resonant structure to provide high, or maximum isolation at one or more frequencies of interest. By resonating the device parasitics, the OFF arm of the switch may behave as a substantially infinite resistor, thereby improving isolation. Such solutions may provide particular benefit for CMOS or Silicon-on-Insulator (SOI) switches, where significant parasitic capacitance can exist between drain-to-body and body-to-source terminals.

FIG. 6 illustrates an embodiment of a switch RF core circuit 630 in a series-shunt configuration. The circuit 630 includes one or more series FETs associated with each of two or more throws (104a, 104b). The circuit 630 further includes one or more additional switch isolation resistor networks. For example, the resistor 150b is connected across the series FET(s) of the arm connecting pole 102a to throw 2 (104b). In certain embodiments, the isolation resistor value(s) can be tuned to provide the ideal isolation depending on the desired frequency of isolation. The parallel resistor 150b, in combination with the drain-to-source parasitc capacitance of the series FETs (141c, 141d) may result in a resonant structure that may effectively create an open circuit for the OFF arm, thereby isolating the two RF ports. The isolation solution illustrated in FIG. 6 may be desirable over other more expensive solutions, as the isolation resistor may not require substantial space and/or expense to implement.

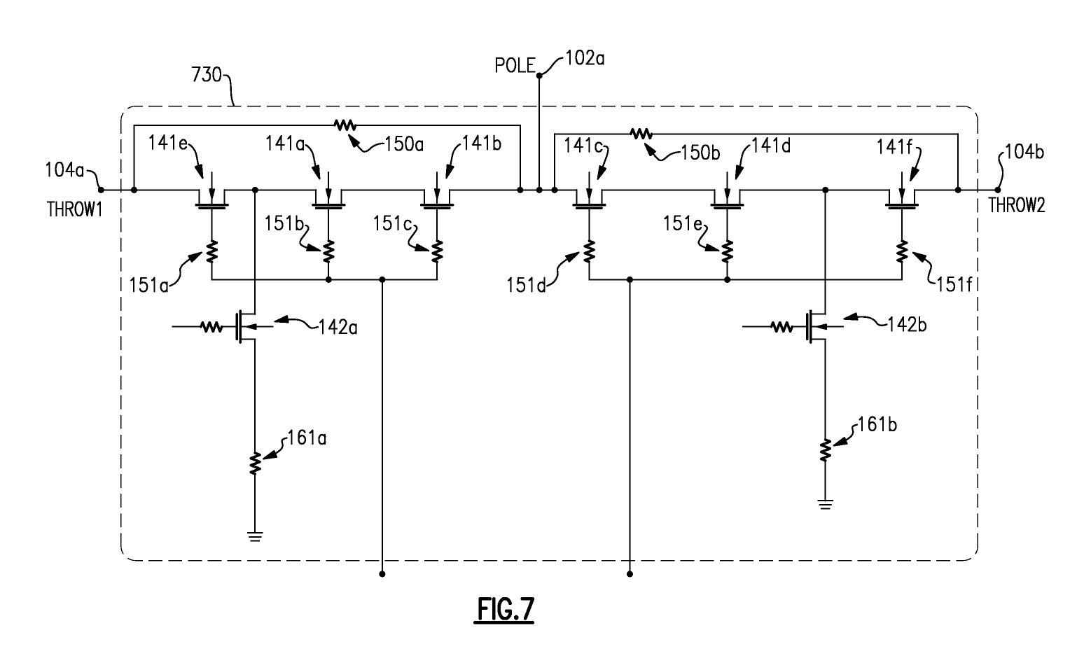

FIG. 7 illustrates an embodiment of a switch RF core circuit 730 in a series-shunt-series configuration. The circuit 730 includes resonant resistors 150a, 150b for switch isolation. As described above, transistor parasitic capacitance for the OFF switch arm can affect insertion loss, isolation, and linearity. In certain embodiments, such capacitance is resonated with a passive device, such as a resistor, or inductor, in order to improve performance. While inductors may be used to resonate the circuit, resistors may advantageously require less space and/or expense than inductors, and therefore may be more desirable. By tuning the resonant resistor 150b, the equivalent capacitance of the corresponding parallel transistors (141c, 141d, 141f) can be resonated, such that when the throw 2 arm of the circuit 730 is in an OFF state, the OFF arm is a substantially open circuit.

With regard to the ON arm of the switch the shunt FET (e.g., 142a) can also be a source of leakage attributable to the parasitic capacitance of the transistor. However, because signal power is not generally transmitted on the shunt arm, the size of the shunt transistor may be relatively small, and therefore the effect of such parasitic capacitance may likewise be small. As a result, in certain embodiments, no resonator is provided in parallel with the shunt transistor(s). However, in certain embodiments, a resonant resistor is disposed in parallel with the shunt resistor(s) on one or more arms of the circuit 730.

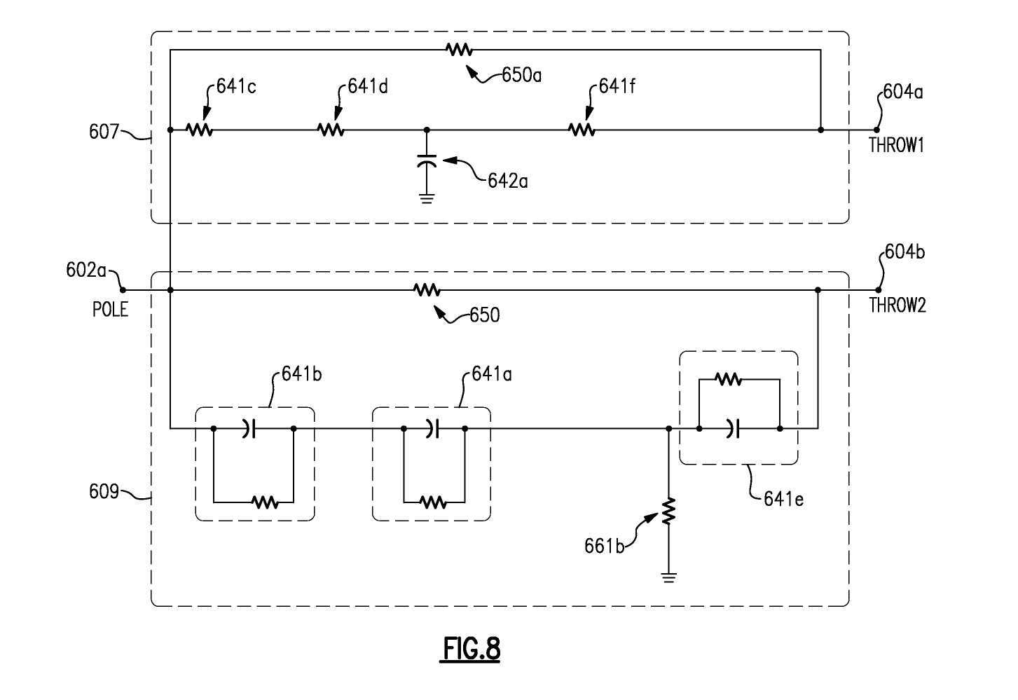

FIG. 8 is a simplified representation of the circuit 730 shown in FIG. 7. The diagram illustrates an ON arm 607 and an OFF arm 609. FIG. 8 shows parallel resistor/capacitor pairings 641a, 641b, 641e on the OFF arm of the switch circuit in place of the FETs illustrated in FIG. 7, wherein the respective resistors (not shown in FIG. 7) are biasing resistors that may be connected across transistor devices for biasing and/or voltage division purposes in embodiments disclosed herein, while the respective capacitors represent parasitic capacitances of the OFF arm transistors, as described herein. The various series resistors illustrated may have values of, for example, 2, 3, 5, or 10 kOhm resistance between drain and source of FET transistors(not shunt)

The number of series transistors used in embodiments disclosed herein may depend on the amount of power applied to the switch for the respective application. For example, although two or three series transistors are illustrated in herein, certain embodiments may comprise six or more series transistors.

Embodiments disclosed herein may have particular applicability in silicon-based switch circuits, such as SOI or CMOS. However, principals and features disclosed herein may be utilized in other processes as well, such as gallium arsenide (GaAs) devices. For GaAs solutions, one or more additional components not illustrated in the associated figures may be desirable or necessary, including one or more DC-blocking capacitors.

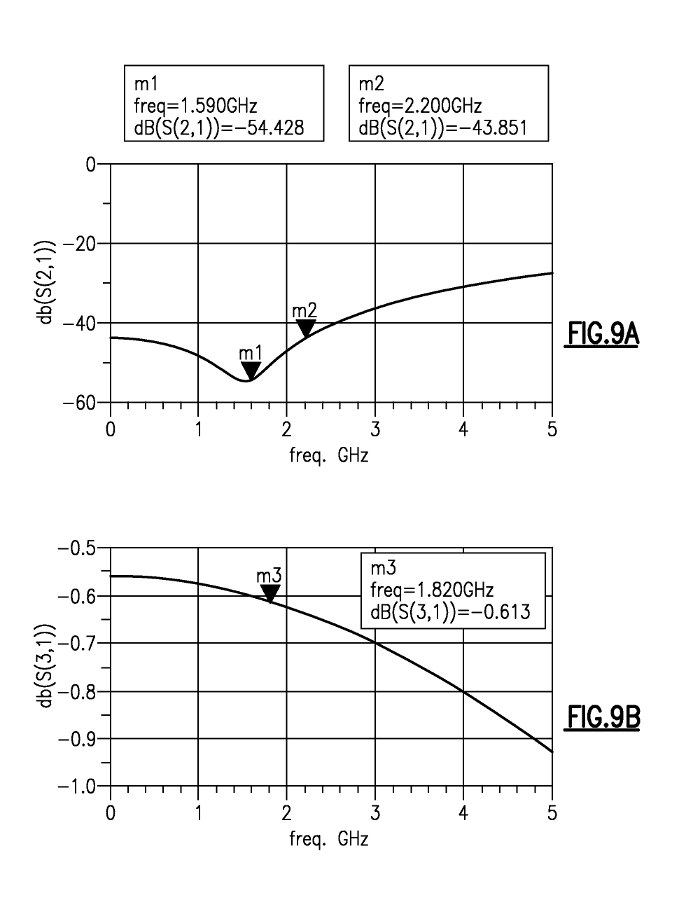

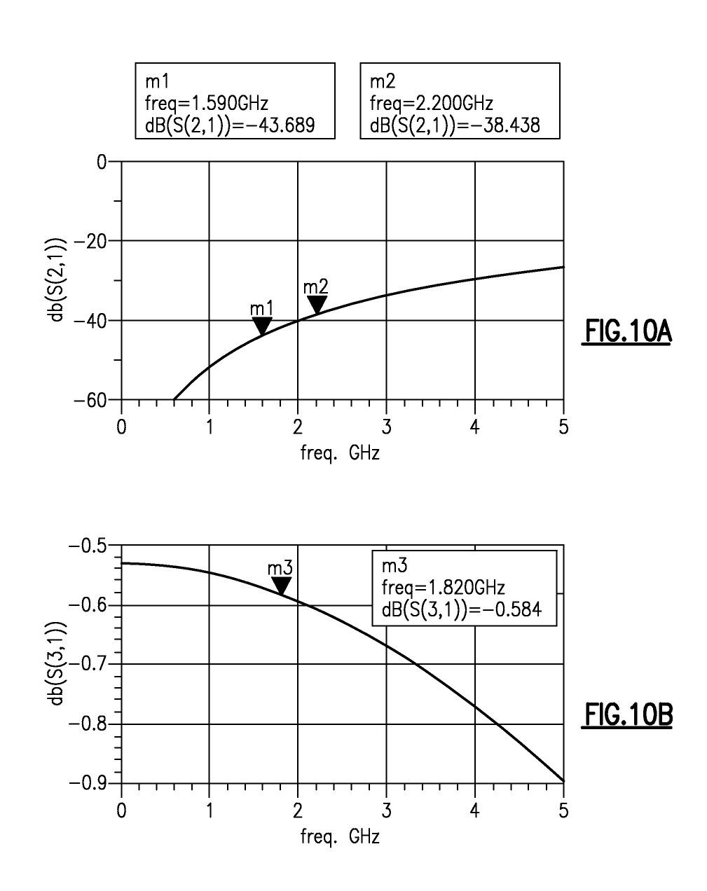

FIG. 9A shows a plot of potential gain magnitude (S(2,1)) over a frequency range of 0 GHz to 5 GHz, while FIG. 9B shows a plot of potential gain magnitude (S(3,1)) over the same frequency range. Parasitic capacitors of drain to body and source to body capacitors together with parallel resistors (e.g., 150a, 150b in FIG. 7) may create a resonance open circuit, thereby promoting isolation, as described herein. FIGS. 10A, 10B show similar potential gain magnitude plots for a circuit embodiment not including the parallel resonant devices.

As shown, at certain points (m1, m2, m3) along the frequency spectrum, the gain magnitude may be less for the respective plots in embodiments including parallel resonant device(s) for switch isolation.

### Semiconductor Die Implementation

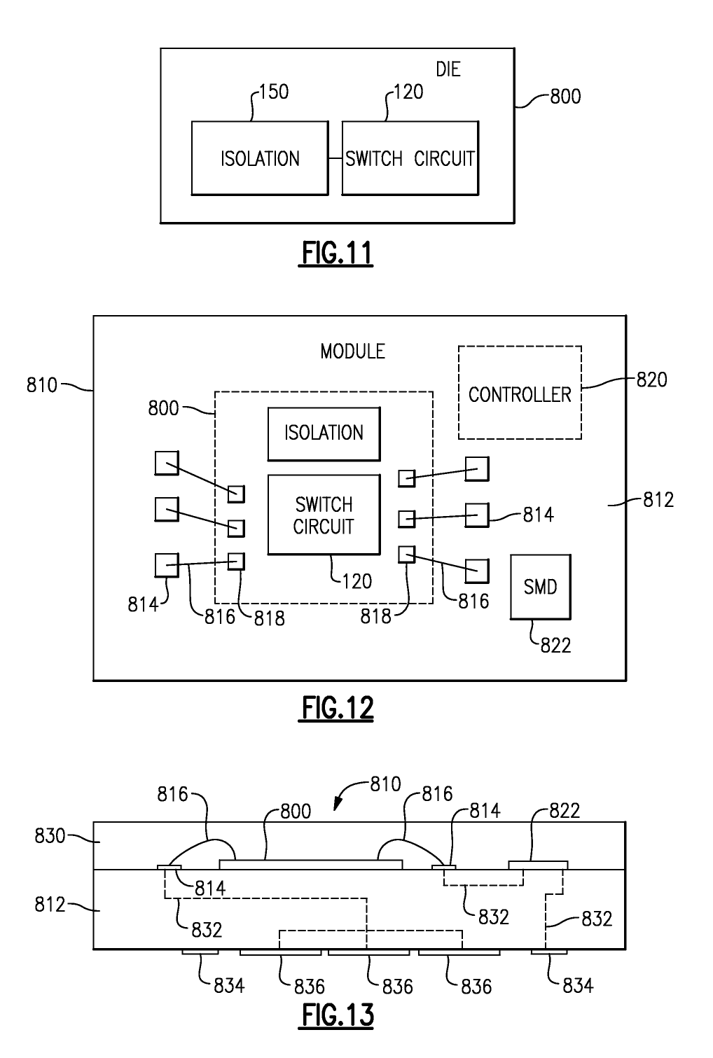

FIG. 11 schematically shows a non-limiting example of implementations on one or more semiconductor die. In some embodiments, a switch circuit 120 and switch isolation circuitry 150 having one or more features as described herein can be implemented on a die 800. While the switch and isolation circuitry are shown on a single die, in certain embodiments, at least some of the switch and/or isolation circuitry can be implemented outside of the die 800 of FIG. 11.

### Packaged Module Implementation

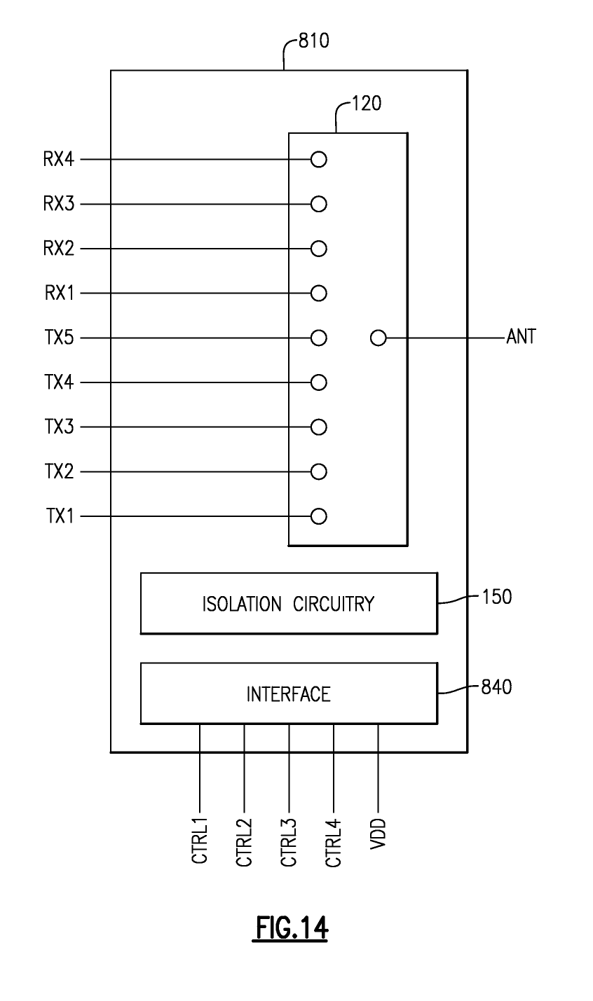

In some embodiments, one or more die having one or more features described herein can be implemented in a packaged module. An example of such a module is shown in FIGS. 12 (plan view) and 13 (side view). A module 810 is shown to include a packaging substrate 812. Such a packaging substrate can be configured to receive a plurality of components, and can include, for example, a laminate substrate. The components mounted on the packaging substrate 812 can include one or more dies. In the example shown, a die 800 having a switching circuit 120 and a bias/coupling circuit 150 is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 832 is depicted as interconnecting the SMD 822 with an external-connection contact pad 834. In yet another example a connection path 832 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

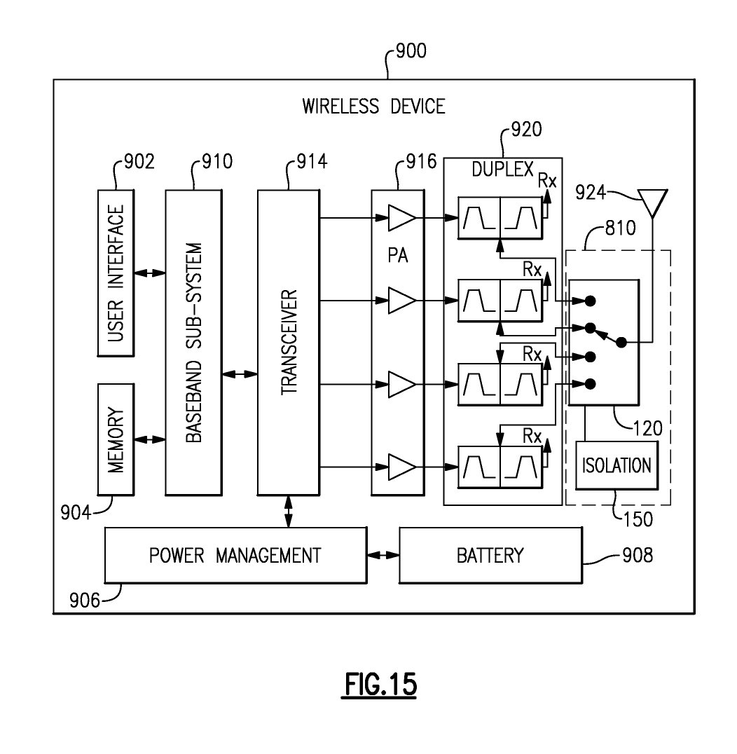

FIG. 14 shows a schematic diagram of an example switching configuration that can be implemented in the module 810 described in reference to FIGS. 12 and 13. In the example, the switch circuit 120 is depicted as being an SP9T switch, with the pole being connectable to an antenna and the throws being connectable to various Rx and Tx paths. Such a configuration can facilitate, for example, multi-mode multi-band operations in wireless devices.

The module 810 can further include an interface for receiving power (e.g., supply voltage VDD) and control signals to facilitate operation of the switch circuit 120 and/or the isolation circuitry 150.

### Wireless Device Implementation

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 15 schematically depicts an example wireless device 900 having one or more advantageous features described herein. In the context of various switches and various biasing/coupling configurations as described herein, a switch 120 associated with isolation circuitry 150, such as one or more passive parallel resonant devices, can be part of a module 810. In some embodiments, such a switch module can facilitate, for example, multi-band multip-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in a known manner. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 810.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 46, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antennas, and additional connectivity features such as Wi-Fi, Bluetooth, and GPS.

While various embodiments of integrated front-end modules have been described, it will be apparent to those of ordinary skill in the art that many more embodiments and implementations are possible. For example, embodiments of integrated FEMs are applicable to different types of wireless communication devices, incorporating various FEM components. In addition, embodiments of integrated FEMs are applicable to systems where compact, high-performance design is desired. Some of the embodiments described herein can be utilized in connection with wireless devices such as mobile phones. However, one or more features described herein can be used for any other systems or apparatus that utilize of RF signals.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio-frequency (RF) switch comprising:
a pole node;
a first throw arm connected between the pole node and a first throw node;
a second throw arm connected between the pole node and a second throw node, the second throw arm including first and second field-effect transistors (FETs); and
a passive device connected on a first end to a source connector of the first FET and on a second end to a drain connector of the second FET.

2. The RF switch of claim 1 wherein the passive device is a resistor.

3. The RF switch of claim 1 wherein the passive device is an inductor.

4. The RF switch of claim 1 wherein the pole node is connected to the first or second end of the passive device.

5. The RF switch of claim 4 wherein the second throw node is connected to the first or second end of the passive device.

6. The RF switch of claim 1 further comprising a first shunt arm connected to the first throw arm and a second shunt arm connected to the second throw arm.

7. The RF switch of claim 6 wherein the second shunt arm is connected to the second throw arm between the first FET and the second FET.

8. The RF switch of claim 1 wherein the first and second FETs are connected in series.

9. The RF switch of claim 1 wherein when the second throw arm is in an OFF state, the passive device is configured to resonate a parasitic capacitance of at least one of the first and second FETs to at least partially isolate the first arm from the second throw node.

10. A method for operating a radio-frequency (RF) switch, the method comprising:
transmitting an RF signal between a pole node and a first throw node;
controlling first and second field-effect transistors (FETs) of a throw arm connected between the pole node and a second throw node so that at least one of the first and second FETs is in an OFF state;
resonating parasitic capacitance associated with one or more of the first and second FETs using a passive device connected on a first end to a source connector of the first FET and on a second end to a drain connector of the second FET.

11. The method of claim 10 wherein the passive device is a resistor.

12. The method of claim 10 further comprising isolating the first throw node from the second throw node at least in part by said resonating.

13. A semiconductor die comprising:
a semiconductor substrate;
a pole node;
a first throw arm formed on the semiconductor substrate and connected between the pole node and a first throw node;
a second throw arm formed on the semiconductor substrate and connected between the pole node and a second throw node, the second throw arm including first and second field-effect transistors (FETs); and
a passive device connected on a first end to a source connector of the first FET and on a second end to a drain connector of the second FET.

14. The semiconductor die of claim 13 wherein the passive device is a resistor.

15. The semiconductor die of claim 13 wherein the passive device is an inductor.

16. The semiconductor die of claim 13 wherein the pole node is connected to the first or second end of the passive device.

17. The semiconductor die of claim 16 wherein the second throw node is connected to the first or second end of the passive device.

18. The semiconductor die of claim 13 further comprising a first shunt arm connected to the first throw arm and a second shunt arm connected to the second throw arm.

19. The semiconductor die of claim 18 wherein the second shunt arm is connected to the second throw arm between the first FET and the second FET.

20. The semiconductor die of claim 13 wherein when the second throw arm is in an OFF state, the passive device is configured to resonate a parasitic capacitance of at least one of the first and second FETs to at least partially isolate the first arm from the second throw node.
